(19) United States
(12) Patent Application Publication
(10) Pub. No.: US 2009/0255630 A1
(43) Pub. Date: Oct. 15, 2009

(54) Substrate processing apparatus and electrode member

(75) Inventors: Kazuyuki Toyoda, Toyama-shi (JP); Shinji Yashima, Toyama-shi (JP); Yuji Takebayashi, Toyama-shi (JP); Takeshi Itoh, Toyama-shi (JP)

Correspondence Address: BIRCH STEWART KOLASCH & BIRCH, PO BOX 747, FALLS CHURCH, VA, 22040-0747, US

(73) Assignee: HITACHI KOKUSAI ELECTRIC INC., TOKYO (JP)

(21) Appl. No.: 11/919,348

(22) PCT Filed: Apr. 26, 2006
(86) PCT No.: PCT/JP2006/308774

§ 371 Date: Oct. 28, 2008

(30) Foreign Application Priority Data
Apr. 28, 2005 (JP) 2005-133388

(51) Int. Cl. H01L 21/465

(52) U.S. Cl. 156/345.43; 257/E21.485

(57) ABSTRACT

Disclosed is a substrate processing apparatus, including: a reaction chamber to process a substrate; a substrate placing member to stack a plurality of substrates thereon in multi-layers at a predetermined distance from one another in the reaction chamber; an introducing section to introduce processing gas into the reaction chamber; an exhaust section to exhaust an inside of the reaction chamber; and a plurality of pairs of comb electrodes, to which alternating current electric power is to be applied, to generate plasma, the plurality of pairs of comb electrodes being disposed in the reaction chamber, wherein each pair of the plurality of pairs of comb electrodes are disposed at a predetermined distance from each of plasma processing faces of the plurality of the substrates to be placed on the substrate placing member.

### BACKGROUND OF THE INVENTION

1. Field of the Invention

The present invention relates to a substrate processing apparatus and an electrode member, and more particularly, to a plasma processing apparatus which etches surfaces of substrates such as a plurality of semiconductor silicon wafers utilizing plasma, form thin films and reforms the surfaces, and to an electrode member which is preferably used for the plasma processing apparatus.

2. Description of the Related Art

In a conventional plasma processing apparatus of this kind, a silicon wafer is placed between electrodes, high frequency alternating current electric power is applied between the electrodes to generate plasma, and the wafer is subjected to plasma processing.

However, since the wafer exists between the electrodes, plasma generated between the electrodes and the silicon wafer is not uniform, and there is a problem that the plasma processing on the silicon wafer surface cannot be carried out uniformly.

### SUMMARY OF THE INVENTION

It is, therefore, a main object of the present invention to provide a plasma processing apparatus capable of enhancing the uniformity of the plasma processing on the substrate surface.

It is another object of the present invention to provide a substrate processing apparatus and an electrode member which can efficiently utilize generated plasma.

According to one aspect of the present invention, there is provided a substrate processing apparatus, comprising:

a reaction chamber to process a substrate;

a substrate placing member to stack a plurality of substrates thereon in multi-layers at a predetermined distance from one another in the reaction chamber;

an introducing section to introduce processing gas into the reaction chamber;

an exhaust section to exhaust an inside of the reaction chamber; and

a plurality of pairs of comb electrodes, to which alternating current electric power is to be applied, to generate plasma, the plurality of pairs of comb electrodes being disposed in the reaction chamber, wherein

each pair of the plurality of pairs of comb electrodes are disposed at a predetermined distance from each of plasma processing faces of the plurality of the substrates to be placed on the substrate placing member.

According to another aspect of the present invention, there is provided a substrate processing apparatus, comprising:

a reaction chamber to process a substrate;

a substrate placing member to stack a plurality of substrates thereon in multi-layers at a predetermined distance from one another in the reaction chamber;

an introducing section to introduce processing gas into the reaction chamber;

an exhaust section to exhaust an inside of the reaction chamber; and

a plurality of electrode members, disposed in the reaction chamber, to generate plasma, wherein

the plurality of electrode members are disposed in the reaction chamber in multi-layers, each of the electrode members is disposed at a predetermined distance from each of plasma processing faces of the plurality of the substrates to be placed on the substrate placing member, and

plasma generation is more suppressed on one sides of the electrode members, which are not opposed to the plasma processing faces of the substrates, than on another sides of the electrode members, which are opposed to the plasma processing faces.

According to another aspect of the present invention, there is provided an electrode member, comprising:

a pair of electrodes; and

a dielectric member surrounding the pair of the electrodes, wherein

a thickness (T1) of the dielectric member on one sides of the electrodes is greater than a thickness (T2) of the dielectric member on another sides of the electrodes.

### BRIEF DESCRIPTION OF DRAWINGS

FIG. 1 is a schematic vertical sectional view for explaining a processing furnace of a plasma processing apparatus according to preferred embodiments 1 to 3 of the present invention;

FIG. 2 is a schematic transverse sectional view for explaining electrodes of the processing furnace of the plasma processing apparatus according to the preferred embodiment 1 of the present invention;

FIG. 3 is a schematic vertical sectional view taken along the line A-A in FIG. 2;

FIG. 4 is a schematic diagram for explaining a connecting structure between the electrodes and an oscillator of the processing furnace of the plasma processing apparatus of the preferred embodiment 1 of the present invention;

FIG. 5 is a schematic vertical sectional view for explaining a discharge state of the plasma processing of the plasma processing apparatus of the preferred embodiment 1 of the present invention;

FIG. 6 is a schematic transverse sectional view for explaining an electrode structure of the processing furnace of the plasma processing apparatus of the preferred embodiments 2 and 3 of the present invention;

FIG. 7 is a schematic vertical sectional view taken along the line B-B in FIG. 6 for explaining the electrode structure of the processing furnace of the plasma processing apparatus of the preferred embodiment 2 of the present invention;

FIG. 8 is a schematic vertical sectional view for explaining a discharge state of the processing furnace of the plasma processing apparatus of the preferred embodiment 2 of the present invention;

FIG. 9 is a schematic vertical sectional view taken along the line B-B in FIG. 6 for explaining the electrode structure of the processing furnace of the plasma processing apparatus of the preferred embodiment 3 of the present invention;

FIG. 10 is a schematic vertical sectional view for explaining a discharge state of the processing furnace of the plasma processing apparatus of the preferred embodiment 3 of the present invention;

FIG. 11 is a schematic perspective view for explaining the plasma processing apparatus of the preferred embodiment of the present invention; and

FIG. 12 is a schematic vertical sectional view for explaining a processing furnace of a comparative plasma processing apparatus.

### DESCRIPTION OF THE PREFERRED EMBODIMENTS

Next, a preferred embodiment of the present invention will be explained.

According to one aspect of the preferred embodiment of the present invention, there is provided a substrate processing apparatus, comprising:

a reaction chamber to process a substrate;

a substrate placing member to stack a plurality of substrates thereon in multi-layers at a predetermined distance from one another in the reaction chamber;

an introducing section to introduce processing gas into the reaction chamber;

an exhaust section to exhaust an inside of the reaction chamber; and

a plurality of pairs of comb electrodes, to which alternating current electric power is to be applied, to generate plasma, the plurality of pairs of comb electrodes being disposed in the reaction chamber, wherein

each pair of the plurality of pairs of comb electrodes are disposed at a predetermined distance from each of plasma processing faces of the plurality of the substrates to be placed on the substrate placing member.

With this configuration, plasma is generated between each pair of comb electrodes, and since no substrate exists between the comb electrodes, the uniformity of the plasma processing on the substrate surface can be enhanced.

With this configuration, the pairs of comb electrodes and the substrates are alternately disposed, and plasma is generated on both sides of each pair of comb electrodes. Therefore, when the plasma etching is carried out, not only films on front surfaces of the substrates, but also films on back surfaces of the substrates can be etched at the same time.

Preferably, each pair of comb electrodes generates plasma which spreads over the entire region of the substrate.

Preferably, each pair of comb electrodes is disposed such that teeth-like electrodes of the comb electrodes are alternately arranged at a predetermined distance on the same plane, and plasma is generated around the teeth-like electrodes of each pair of comb electrodes by applying alternating current electric power between each pair of comb electrodes.

Preferably, the substrate processing apparatus further comprises a dielectric member to cover teeth-like electrodes of the pair of comb electrodes, wherein one faces of the dielectric members, which are to be opposed to the plasma processing faces of the substrates, are substantially flat.

By covering the teeth-like electrodes of the pair of comb electrodes with the dielectric member, plasma does not come into direct contact with the electrodes.

Since the teeth-like electrodes of the pair of the comb electrodes are covered with a dielectric, and one face of the dielectric member is substantially flat, the electrodes can be formed such that creeping discharge is carried out on the flat face of the dielectric member. As a result, uniform and flat plasma is generated and with this, the substrates can be processed uniformly.

According to another aspect of the preferred embodiment of the present invention, there is provided a substrate processing apparatus, comprising:

a reaction chamber to process a substrate;

a substrate placing member to stack a plurality of substrates thereon in multi-layers at a predetermined distance from one another in the reaction chamber;

an introducing section to introduce processing gas into the reaction chamber;

an exhaust section to exhaust an inside of the reaction chamber; and

a plurality of electrode members, disposed in the reaction chamber, to generate plasma, wherein

the plurality of electrode members are disposed in the reaction chamber in multi-layers, each of the electrode members is disposed at a predetermined distance from each of plasma processing faces of the plurality of the substrates to be placed on the substrate placing member, and

plasma generation is more suppressed on one sides of the electrode members, which are not opposed to the plasma processing faces of the substrates, than on another sides of the electrode members, which are opposed to the plasma processing faces.

With this, plasma generation from one sides of the electrode members, which are not opposed to the plasma processing faces of the substrates, can be suppressed. Therefore, electric power consumption can be suppressed and the generated plasma can efficiently be utilized.

It is possible to prevent unnecessary products from adhering to one sides which are not opposed to the plasma processing faces of the substrates.

Preferably, each of the plurality of the electrode members includes a pair of electrodes and a dielectric member covering the pair of electrodes, and

a thickness (T1) of the dielectric member of the electrode member on one side which is not opposed to the plasma processing face of the substrate is greater than a thickness (T2) of the dielectric member of the electrode member on another side which is opposed to the plasma processing face.

Preferably, T1:T2≧2:1.

Preferably, each of the plurality of the electrode members includes a pair of comb electrodes.

According to another aspect of the preferred embodiment of the present invention, there is provided an electrode member, comprising:

a pair of electrodes; and

a dielectric member surrounding the pair of the electrodes, wherein

a thickness (T1) of the dielectric member on one sides of the electrodes is greater than a thickness (T2) of the dielectric member on another sides of the electrodes.

With this, plasma generation from the thicker side of the dielectric member can be suppressed, electric power consumption can be suppressed and the generated plasma can be utilized efficiently.

Preferably, T1:T2≧2:1.

Preferably, the electrode is of a comb-shape.

Next, preferred embodiments of the present invention will be explained in more detail with reference to the drawings.

### Embodiment 1

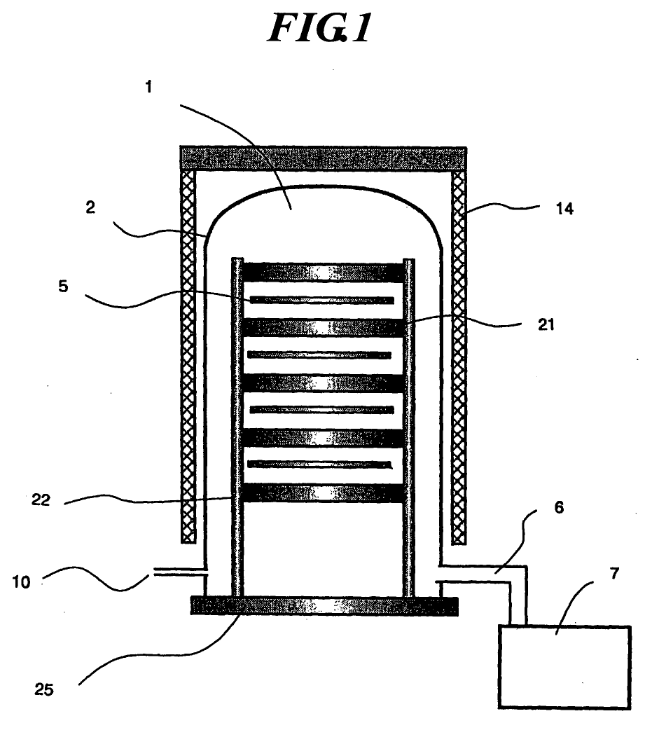

Referring to FIG. 1, a reaction chamber 1 has a hermetic structure by a reaction tube 2 and a seal cap 25. A heater 14 is provided around the reaction tube 2 such as to surround the reaction chamber 1. The reaction tube 2 comprises a dielectric made of quartz or the like.

A gas introduction port 10 is in communication with the reaction chamber 1 so that a desired gas can be introduced into the reaction chamber 1. The reaction chamber 1 is connected to a pump 7 through an exhaust tube 6 so that gas can be exhausted from the reaction chamber 1.

A boat 22 is placed on the seal cap 25 in the reaction chamber 1. The boat 22 usually comprises a dielectric such as quartz or ceramics.

Electrode plates 21 are mounted in multi-layers on the boat 22 at given distances from one another. To-be processed substrates 5 such as semiconductor silicon wafers are placed between the electrode plates 21 which are disposed in multi-layers on the boat 22 such that to-be processed substrates 5 do not come into contact with the electrode plates 21.

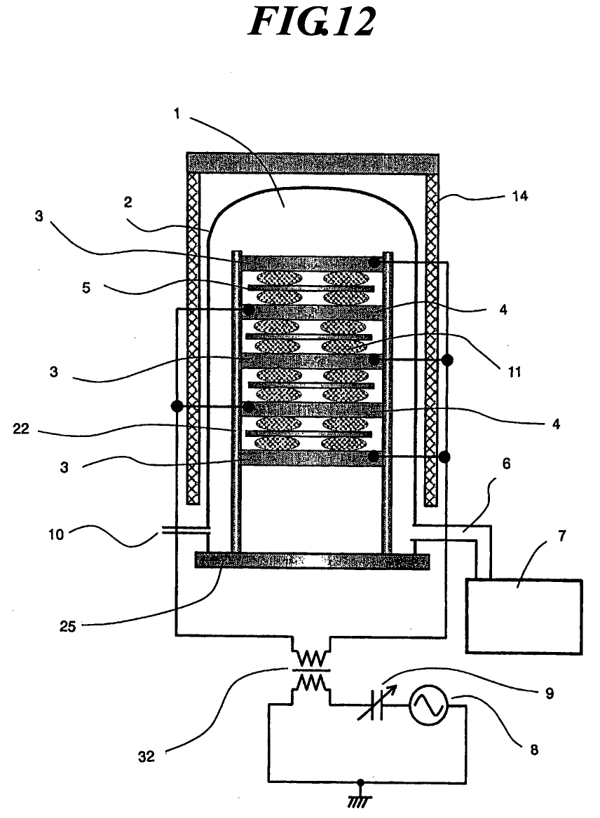

The boat 22 is provided with grooves (not shown) for placing the to-be processed substrates 5 so that the to-be processed substrates 5 can be placed between the electrode plates 21 provided on the boat 22 at equal distances from one another. The to-be processed substrates 5 can be automatically transferred by a to-be processed substrate transfer robot (see wafer transfer device 112 in FIG. 11).

When the to-be processed substrates 5 are transferred, tweezers (not shown) on which the to-be processed substrates 5 of the to-be processed substrate transfer robot are inserted between the electrode plates 21, the to-be processed substrates 5 can be held such that they are directly placed in the grooves formed in the boat 22. Therefore, unlike the case where the to-be processed substrates 5 are placed directly on the susceptor electrodes, pins for temporarily supporting the to-be processed substrates 5 are unnecessary. Therefore, the electrode plate 21 is not formed with a hole through which a pin passes.

The to-be processed substrates 5 and the electrode plates 21 are disposed such that they do not come into contact with each other. Therefore, there is no receiving and delivering operation using the pin, it is easier to transfer the to-be processed substrates 5 correspondingly as compared with a structure in which the to-be processed substrates 5 are placed on the susceptor.

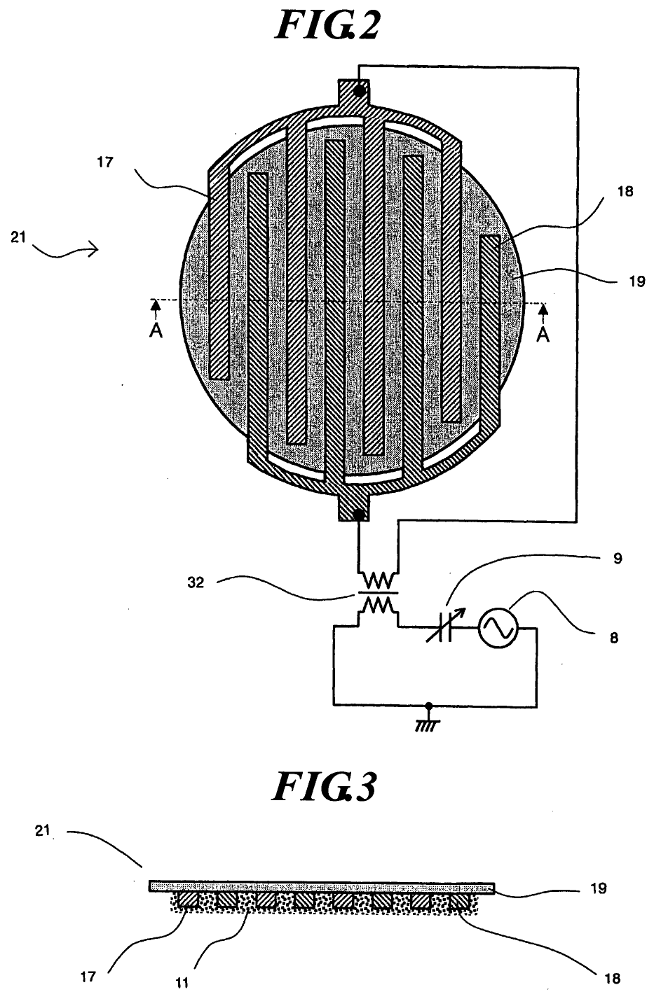

Referring to FIG. 2, comb electrodes C 17 and D 18 made of dielectric material are disposed on an electrode base 19 such that the comb shapes of both the electrodes alternately mesh each other on the same plane. The electrode plates 21 comprising a combination of the comb electrodes are mounted on the boat 22 at given distances from one another in multi-layers.

Referring to FIGS. 2 and 3, the comb electrodes C 17 and D 18 are disposed on a lower face of the electrode base 19 made of dielectric material such that the comb shapes of both the electrodes alternately mesh each other on the same plane. The electrode plate 21 comprises the electrodes C 17 and D 18 and the electrode base 19.

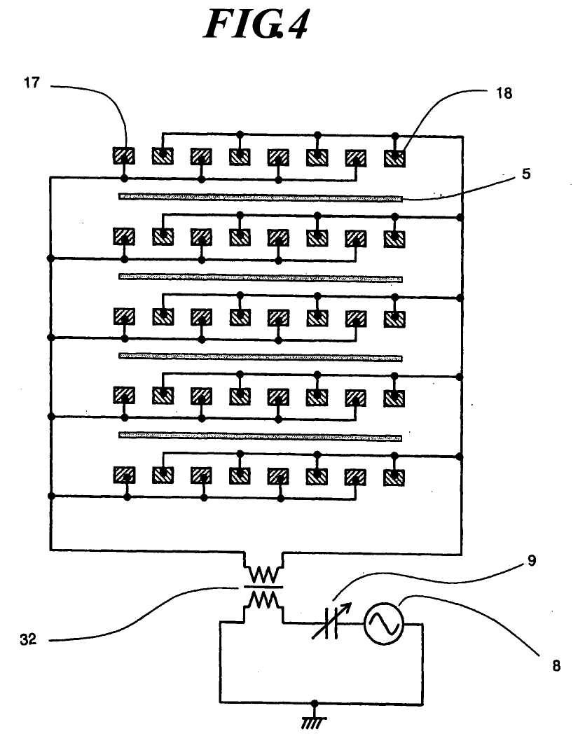

Referring to FIGS. 2 and 4, alternating current electric power which is output from an oscillator 8 can be applied to the electrodes C 17 and D 18 of each of the electrode plates 21 through a matching device 9. The frequency of the alternating current electric power which can be used here is low frequency of several (KHz) to high frequency of 13.56 (MHz).

An insulating transformer 32 is provided at an intermediate portion of a path through which the alternating current electric power is supplied, and the electrodes C 17 and D 18 are insulated from the ground. Since the alternating current electric power supply system is provided with the insulating transformer 32, electric fields whose phases are different from each other by 180 degrees are applied to the electrodes C 17 and D 18.

The alternating current electric power whose phases are different from each other by 180 degrees is applied to the electrodes C 17 and D 18 in the reaction chamber 1, gas introduced from the gas introduction port 10 is brought into plasma, and the to-be processed substrates 5 placed on the boat 22 are processed.

As shown in FIGS. 3 and 4, if the alternating current electric power which is output from the oscillator 8 is supplied to the electrodes C 17 and D 18 through the matching device 9, plasma 11 can be generated around the electrodes. If the electrodes C 17 and D 18 are insulated from the ground by the insulating transformer 32, it is possible to generated plasma 11 intensively around the electrode portions of the electrodes C 17 and D 18 arranged in the form of comb.

Since there is no obstruction such as wafers between the electrodes C 17 and D 18 to which alternating current electric power is applied, stable discharge can be obtained in a certain state determined by a structure of the electrodes, pressure in the reaction chamber and kinds of gas to be supplied. The uniformity of plasma can be improved by increasing or decreasing the number of teeth of the comb electrodes C 17 and D 18, or by adjusting the distance between the electrode plate 21 and the to-be processed substrate 5.

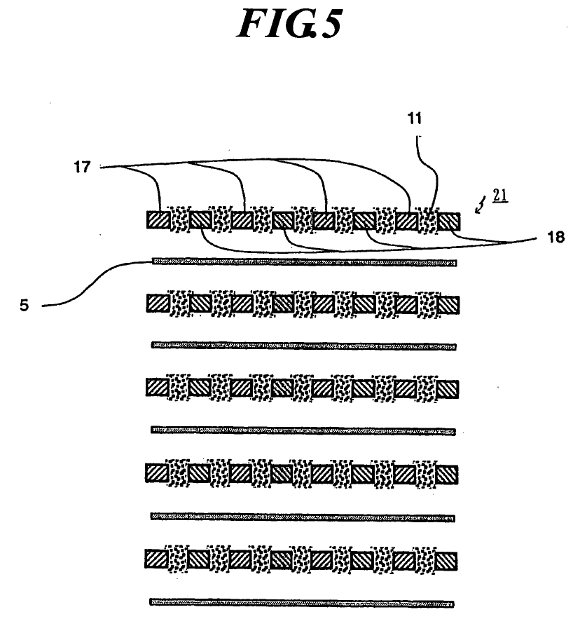

If the to-be processed substrate 5 exists between the electrodes as in the conventional technique, electric power is concentrated locally between the electrodes, and plasma is generated unevenly in some cases. In the preferred embodiment of the present invention, as shown in FIGS. 3 and 5, alternating current electric power is applied only between the comb electrodes C 17 and D 18 in a state where there is no obstruction such as the to-be processed substrate 5 (e.g. wafer). Therefore stable plasma 11 is generated irrespective of presence and absence of the to-be processed substrate 5.

### Embodiment 2

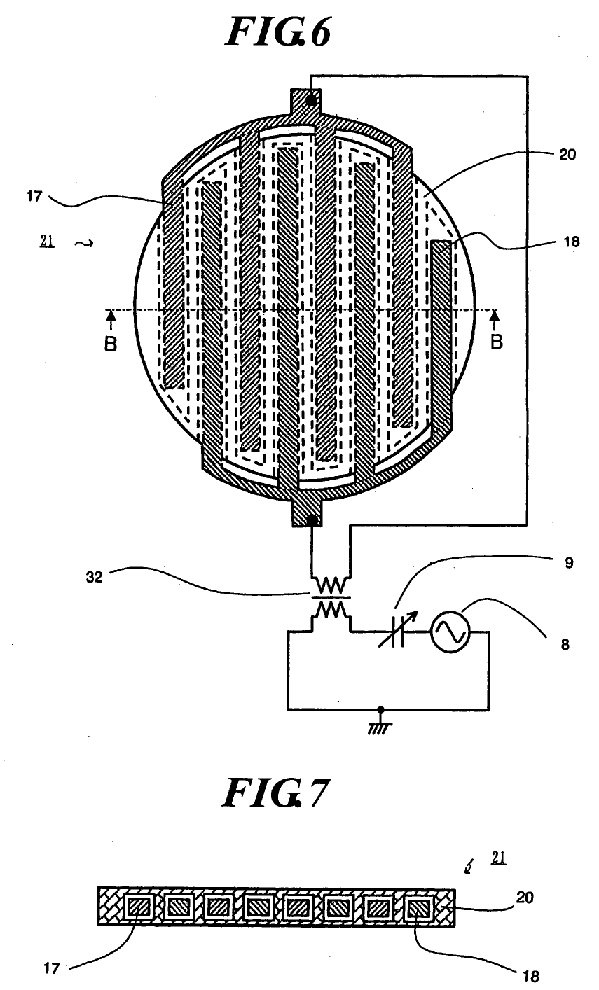

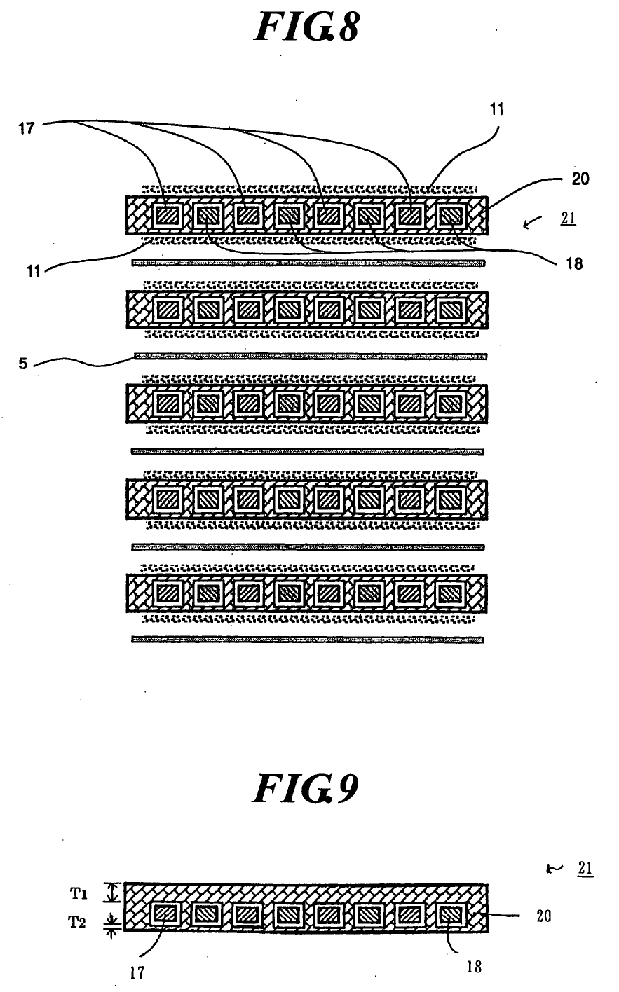

In the case of the comb electrodes, plasma 11 is generated intensively between the electrodes C 17 and D as shown in FIGS. 3 and 5, but if the electrodes C 17 and D 18 are covered with a dielectric cover 20 as shown in FIGS. 6 to 8, uniform plasma 11 can be generated relatively flatly on a surface of the dielectric cover 20 by creeping discharge. With this structure, the to-be processed substrates 5 can be processed more uniformly.

Since the electrodes C 17 and D 18 are covered with the dielectric so that plasma 11 does not come into direct contact with the electrode member, it is possible to prevent impurities from being discharged from the electrode member.

### Embodiment 3

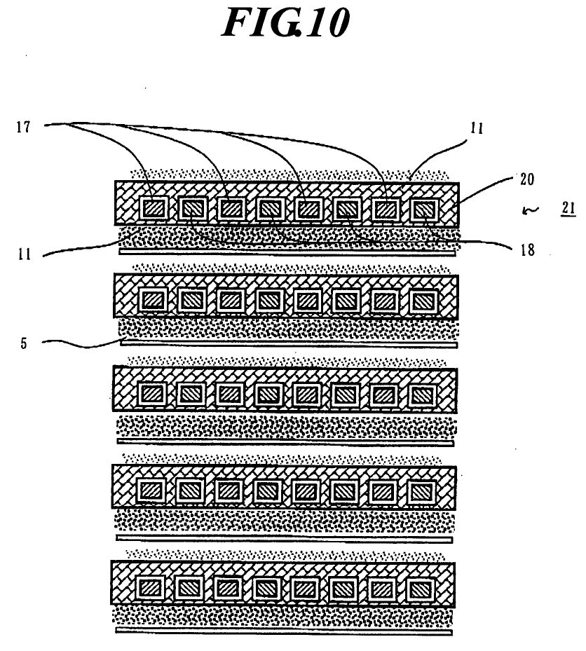

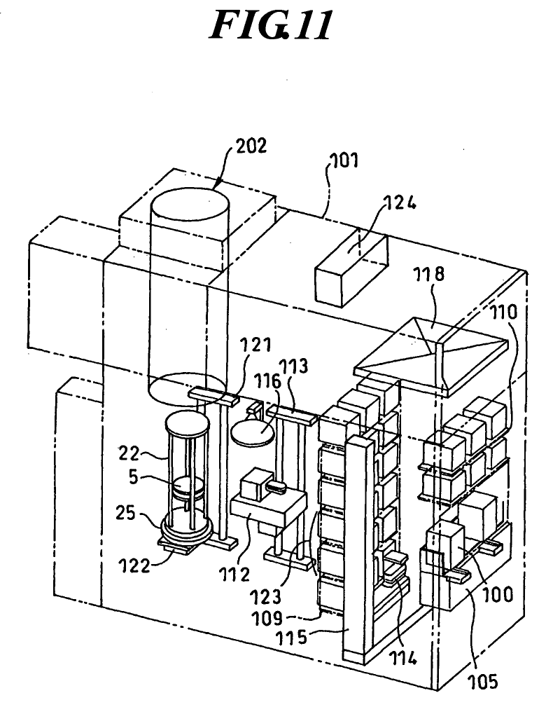

The structure of this embodiment is substantially the same as the embodiment 2, but as shown in FIGS. 9 and 10, one side (upper side) of the dielectric cover 20, which is not opposed to a plasma processing face (upper surface) of the to-be processed substrate 5 is thicker than the other side (lower side) of the dielectric cover 20, which is opposed to the plasma processing face (upper surface) of the to-be processed substrate 5.

With this, strong plasma is generated on the lower side of the electrode plate when alternating current electric power which is output from the oscillator 8 is applied to the electrodes C 17 and D 18 of each of the electrode plates 21 as shown in FIG. 10.

If the alternating current electric power applied to the electrodes C 17 and D 18 of each of the electrode plates 21 is increased, plasma is generated also on the upper side of the electrode plate 21, but this plasma is weaker than plasma on the lower side.

If the thickness of the dielectric on the upper side of the electrode plate 21 is increased, capacity between plasma and the electrodes C 17 and D 18 of each of the electrode plates 21 becomes small, a supply amount of alternating current electric power becomes smaller than that of the lower side and thus, the plasma is weakened.

If a thickness of the dielectric cover higher than the electrodes C 17 and D 18 is defined as T1 and a thickness of the lower side of the dielectric cover is defined as T2, it is preferable that T1:T2=2:1 or greater.

In this embodiment, plasma is strongly generated on the side of the plasma processing face (upper surface) of the to-be processed substrate 5, making electric power for generating plasma is efficient.

Moreover, it is possible to prevent unnecessary products from adhering to a back surface of the to-be processed substrate 5.

Next, the operation of this apparatus will be explained.

In a state where pressure is the reaction chamber 1 is atmospheric pressure, the seal cap 25 on which the electrode plates 21 are placed on the boat 22 in multi-layers is lowered using an elevator mechanism (see elevator member 122 in FIG. 11), a necessary number of to-be processed substrates 5 are placed between electrode plates 21 of the boat 22 one by one by the to-be processed substrate transfer robot (see wafer transfer device 112 in FIG. 11). Then, the seal cap 25 is brought upward to bring the boat 22 into the reaction chamber 1. FIG. 1 shows a state where four to-be processed substrates 5 are placed.

Then, the heater 14 is powered on to heat the members in the reaction chamber 1 such as the to-be processed substrates 5, the reaction tube 2 and the electrode plates 21, to a predetermined temperature.

At the same time, gas in the reaction chamber 1 is exhausted by the pump 7 through the exhaust tube 6.

If the temperature of the to-be processed substrate 5 reaches a predetermined value, a reaction gas is introduced into the reaction chamber 1 from the gas introduction port 10, and the pressure in the reaction chamber 1 is held at a predetermined value by a pressure adjusting mechanism (not shown).

If the pressure in the reaction chamber 1 reaches the predetermined pressure, high frequency electric power which is output from the oscillator 8 is supplied through the matching device 9 to the electrodes C 17 and D 18 of electrode plates 21 stacked in multi-layers to generate plasma, and the to-be processed substrates 5 are processed.

According to the preferred embodiment of the present invention, since alternating current electric power is applied between the comb electrodes C 17 and D 18, stable plasma is generated irrespective of presence and absence of the to-be processed substrate 5.

If the pair of comb electrodes is covered with the dielectric 20 and one face of the dielectric cover 20, which is opposed to the surface of the to-be processed substrate 5, is flat, creeping discharge is generated on the flat dielectric face, and uniform and flat plasma is generated. With this, the to-be processed substrates 5 can be processed more uniformly.

Since the pair of comb electrodes is covered with the dielectric 20, and plasma and the electrode member do not come into direct contact with each other, it is possible to prevent impurities from being discharged from the electrode member.

Next, an outline of the plasma processing apparatus of the preferred embodiment of the present invention will be explained with reference to FIG. 11.

A cassette stage 105 as a holder delivery member for giving and receiving cassettes 100 as an accommodation container between an external transfer device (not shown) is provided in the casing 101 on the front surface side. A cassette elevator 115 as elevator means is provided behind the cassette stage 105. A cassette moving machine 114 as transfer means is mounted on the cassette elevator 115. Cassette shelves 109 as mounting means of the cassettes 100 are provided behind the cassette elevator 115. Auxiliary cassette shelves are provided above the cassette stage 105. A clean unit 118 is provided above the auxiliary cassette shelves so that clean air flows through the casing 101.

A processing furnace 202 is provided above a rear portion of the casing 101. A boat elevator 121 as elevator means is provided below the processing furnace 202. The boat elevator 121 vertically moves the boat 22 as substrate holding means which hold wafers 5 as substrates in horizontal attitude in multistage manner. A seal cap 25 as a lid is mounted on a tip end of the elevator member 122 mounted on the boat elevator 121, and the seal cap 22 vertically supports the boat 22. A transfer elevator 113 as elevator means is provided between the boat elevator 121 and the cassette shelves 109. A wafer moving machine 112 as transfer means is mounted on the transfer elevator 113. A furnace opening shutter 116 as closing means for air-tightly closing a wafer carry in/out port 131 on a lower side of the processing furnace 202 is provided beside the boat elevator 121. The furnace opening shutter 116 has an opening/closing mechanism.

The cassettes 100 into which wafers 5 are loaded are carried onto the cassette stage 105 from the external transfer device (not shown) in such an attitude that the wafers 5 are oriented upward, and the cassettes 100 are rotated 90 degrees on the cassette stage 105 such that the wafers 5 are in the horizontal attitudes. The cassettes 100 are transferred from the cassette stage 105 to the cassette shelves 109 or the auxiliary cassette shelves 110 in cooperation with vertical motion and lateral motion of the cassette elevator 115 and forward and backward motion and rotation of the cassette moving machine 114.

Transfer shelves 123 in which cassettes 100 to be transferred by the wafer moving machine 112 are included in the cassette shelves 109. The cassettes 100, which contain the wafers 5 to be transferred, are transferred to the transfer shelves 123 by the cassette elevator 115 and the cassette moving machine 114.

When the cassettes 100 are transferred to the transfer shelves 123, the wafers 5 are transferred to the boat 22, which is in the lowered state, from the transfer shelves 123 in cooperation with forward and backward motion and rotation of the wafer moving machine 112 and vertical motion of the transfer elevator 113.

When a predetermined number of wafers 5 are transferred to the boat 22, the boat 22 is inserted into the processing furnace 202 by the boat elevator 121, and the processing furnace 202 is air-tightly closed by the seal cap 25. The wafers 5 are heated in the air-tightly closed processing furnace 202, processing gas is supplied into the processing furnace 202 and the wafers 5 are processed.

When the processing of the wafers 5 is completed, the wafers 5 are transferred to the cassettes 100 on the transfer shelves 123 from the boat 22 in the reverse procedure to the above-described procedure, the cassettes 100 are transferred from the transfer shelves 123 to the cassette stage 105 by the cassette moving machine 114, and are transferred out from the casing 101 by the external transfer device (not shown).

When the boat 22 is lowered, the furnace opening shutter 116 air-tightly closes the wafer carry in/out port 131 of the processing furnace 202 so as to prevent outside air from being mixed into the processing furnace 202.

The transfer operation of the cassette moving machine 114 is controlled by transfer operation control means 124.

Next, a comparative example will be explained with reference to FIG. 12.

FIG. 12 is a schematic vertical sectional view for explaining a processing furnace of a comparative plasma processing apparatus.

A boat 22 comprising a dielectric is provided in a reaction chamber 1. Electrodes A 3 and electrodes B 4 comprising conductive material are alternately stacked in multi-layers at equal spaces and are mounted on the boat 22 such that the electrodes do not come into contact with to-be processed substrates 5.

High frequency alternating current electric power (e.g. 13.56 MHz) which is output from an oscillator 8 can be applied to the electrodes A 3 and electrodes B 4 through a matching device 9. An insulating transformer 32 is provided at an intermediate portion of a path through which the alternating current electric power is supplied, and the electrodes A 3 and electrodes B 4 are insulated from the ground. Alternate current electric power whose phases are different from each other by 180 degrees is applied to the electrodes A 3 and electrodes B 4 in the reaction chamber 1, gas introduced from the gas introduction port 10 is brought into plasma to generate plasma 11, and to-be processed substrates 5 placed between the electrodes A 3 and electrodes B 4 on the boat 22 are processed.

If the plasma 11 is generated in this manner, and if the to-be processed substrates 5 are silicon wafers, plasma 11 is generated in the form of doughnut between the silicon wafers and the electrodes A 3 or the electrodes B 4. Therefore, the surfaces of the silicon wafers are processed unevenly due to the doughnut shape of the plasma.

The entire disclosures of Japanese Patent Application No. 2005-133388 filed on Apr. 28, 2005 including specification, claims, drawings and abstract are incorporated herein by reference in its entirety.

Although various exemplary embodiments have been shown and described, the invention is not limited to the embodiments shown. Therefore, the scope of the invention is intended to be limited solely by the scope of the claims that follow.

As explained above, according to one aspect of the preferred embodiment of the present invention, the uniformity of the plasma processing on a surface of a substrate can be enhanced.

According to another aspect of the preferred embodiment of the present invention, the generated plasma can efficiently be utilized.

As a result, the present invention can preferably be utilized for a plasma processing apparatus which etches surfaces of substrates such as a plurality of semiconductor silicon wafers utilizing plasma, forms thin films, and reforms the surfaces. The present invention can also preferably be utilized for an electrode member which is preferably used for the plasma processing apparatus.

1. A substrate processing apparatus, comprising:
a reaction chamber to process a substrate;
a substrate placing member to stack a plurality of substrates thereon in multi-layers at a predetermined distance from one another in the reaction chamber;
an introducing section to introduce processing gas into the reaction chamber;
an exhaust section to exhaust an inside of the reaction chamber; and
a plurality of pairs of comb electrodes, to which alternating current electric power is to be applied, to generate plasma, the plurality of pairs of comb electrodes being disposed in the reaction chamber, wherein
each pair of the plurality of pairs of comb electrodes are disposed at a predetermined distance from each of plasma processing faces of the plurality of the substrates to be placed on the substrate placing member.

2. The substrate processing apparatus according to claim 1, further comprising a dielectric member to cover teeth-like electrodes of the pair of comb electrodes, wherein one faces of the dielectric members, which are to be opposed to the plasma processing faces of the substrates, are substantially flat.

3. A substrate processing apparatus, comprising:
a reaction chamber to process a substrate;
a substrate placing member to stack a plurality of substrates thereon in multi-layers at a predetermined distance from one another in the reaction chamber;
an introducing section to introduce processing gas into the reaction chamber;
an exhaust section to exhaust an inside of the reaction chamber; and
a plurality of electrode members, disposed in the reaction chamber, to generate plasma, wherein
the plurality of electrode members are disposed in the reaction chamber in multi-layers, each of the electrode members is disposed at a predetermined distance from each of plasma processing faces of the plurality of the substrates to be placed on the substrate placing member, and
plasma generation is more suppressed on one sides of the electrode members, which are not opposed to the plasma processing faces of the substrates, than on another sides of the electrode members, which are opposed to the plasma processing faces.

4. The substrate processing apparatus according to claim 3, wherein
each of the plurality of the electrode members includes a pair of electrodes and a dielectric member covering the pair of electrodes, and
a thickness (T1) of the dielectric member of the electrode member on one side which is not opposed to the plasma processing face of the substrate is greater than a thickness (T2) of the dielectric member of the electrode member on another side which is opposed to the plasma processing face.

5. The substrate processing apparatus according to claim 4, wherein
T1:T2≧2:1.

6. The substrate processing apparatus according to claim 3, wherein
each of the plurality of the electrode members includes a pair of comb electrodes.

7. An electrode member, comprising:
a pair of electrodes; and
a dielectric member surrounding the pair of the electrodes, wherein
a thickness (T1) of the dielectric member on one sides of the electrodes is greater than a thickness (T2) of the dielectric member on another sides of the electrodes.

8. The electrode member according to claim 7, wherein
T1:T2≧2:1.

9. The electrode member according to claim 7, wherein the electrode is of a comb-shape.
